(19) United States
(12) Patent Application Publication
(10) Pub. No.: US 2026/0255890 A1
(43) Pub. Date: Aug. 27, 2026

(54) IN-SITU PRODUCTION OF H2S OR H2SE DURING GROWTH OF 2D TRANSITION METAL DISULFIDE AND/OR DISELENIDE FILMS

(71) Applicant: Merck Patent GmbH, Darmstadt (DE)

(72) Inventors: Michael Miller, San Jose, CA (US); Randall Higuchi, San Jose, CA (US); Thong NGO, San Jose, CA (US); Karl Littau, Palo Alto, CA (US)

(21) Appl. No.: 18/877,058

(22) PCT Filed: Jul. 7, 2023
(86) PCT No.: PCT/EP2023/068846

§ 371 Date: Dec. 19, 2024

Related U.S. Application Data
(60) Provisional application No. 63/368,100, filed on Jul. 11, 2022.

(51) Int. Cl. H10P 14/24; C23C 16/30; C23C 16/44; C23C 16/448; C23C 16/455; H10P 14/20

(52) U.S. Cl. CPC H10P 14/24; C23C 16/305; C23C 16/4408; C23C 16/4488; C23C 16/45553; H10P 14/3436

(57) ABSTRACT

The disclosed and claimed subject matter relates to a method for the in-situ production of H₂S and/or H₂Se during the growth of 2D transition metal disulfide and/or diselenide containing films.

### BACKGROUND

### Field

The disclosed and claimed subject matter relates to a method for the in-situ production of H₂S and/or H₂Se during the growth of 2D transition metal disulfide and/or diselenide containing films.

### Related Art

For transition metal-containing films used in semiconductor and electronics applications, Chemical Vapor Deposition (CVD) and Atomic Layer Deposition (ALD) have been applied as the main deposition techniques for producing thin films for semiconductor devices. These methods enable the achievement of conformal films (metal, metal oxide, metal nitride, metal silicide, and the like) through chemical reactions of transition metal-containing compounds (precursors). The chemical reactions occur on surfaces which may include metals, metal oxides, metal nitrides, metal silicides, silicon dioxide, silicon nitride, and other surfaces. In CVD and ALD, the precursor molecule plays a critical role in achieving high quality films with high conformality and low impurities. The temperature of the substrate in CVD and ALD processes is an important consideration in selecting a precursor molecule. Higher substrate temperatures, in the range of 150 to 500 degrees Celsius (° C.), promote a higher film growth rate. The preferred precursor molecules must be stable in this temperature range. The preferred precursor is capable of being delivered to the reaction vessel in a liquid phase. Liquid phase delivery of precursors generally provides a more uniform delivery of the precursor to the reaction vessel than solid phase precursors.

CVD and ALD processes are increasingly used as they have the advantages of enhanced compositional control, high film uniformity, and effective control of doping. Moreover, CVD and ALD processes provide excellent conformal step coverage on highly non-planar geometries associated with modern microelectronic devices.

CVD is a chemical process whereby precursors are used to form a thin film on a substrate surface. In a typical CVD process, the precursors are passed over the surface of a substrate (e.g., a wafer) in a low pressure or ambient pressure reaction chamber. The precursors react and/or decompose on the substrate surface creating a thin film of deposited material. Plasma can be used to assist in reaction of a precursor or for improvement of material properties. Volatile by-products are removed by gas flow through the reaction chamber. The deposited film thickness can be difficult to control because it depends on coordination of many parameters such as temperature, pressure, gas flow volumes and uniformity, chemical depletion effects, and time.

ALD is a chemical method for the deposition of thin films. It is a self-limiting, sequential, unique film growth technique based on surface reactions that can provide precise thickness control and deposit conformal thin films of materials provided by precursors onto surfaces substrates of varying compositions. In ALD, the precursors are separated during the reaction. The first precursor is passed over the substrate surface producing a monolayer on the substrate surface. Any excess unreacted precursor is pumped out of the reaction chamber. A second precursor or co-reactant is then passed over the substrate surface and reacts with the first precursor, forming a second monolayer of film over the first-formed monolayer of film on the substrate surface. Plasma may be used to assist with reaction of a precursor or co-reactant or for improvement in materials quality. This cycle is repeated to create a film of desired thickness.

Thin films, and in particular thin metal-containing films, have a variety of important applications, such as in nanotechnology and the fabrication of semiconductor devices. Examples of such applications include capacitor electrodes, gate electrodes, adhesive diffusion barriers and integrated circuits.

In order to grow a 2D transition metal disulfide film using H₂S and/or a 2D transition metal diselenide film using H₂Se, one has previously needed to supply H₂S and/or H₂Se by way of connected gas bottles or facilitized H₂S supply to the growth chamber. Use of H₂S and/or H₂Se supplied external to the chamber presents, however, many complications due to their toxicity. Minimally, there are significant investitures required to acquire and install the relevant equipment (e.g., gas detectors and safety systems, and go through the toxic and fire permitting processes) needed to safely use externally supplied H₂S and/or H₂Se in deposition processes. In addition, the use of externally supplied H₂S and/or H₂Se can increase processing times.

The disclosed and claimed method addresses and largely eliminates these concerns by providing for the in-situ production of H₂S and/or H₂Se inside a deposition chamber during the deposition of 2D metal dichalcogenide films.

### SUMMARY

The disclosed and claimed subject matter relates to a method for the in-situ production of H₂S and/or H₂Se during the growth of 2D transition meta disulfide and/or diselenide containing films by coinjection of (R¹R²R³Si)₂X and NH₃ into a deposition chamber to produce H₂X where R¹, R² and R³ are each independently hydrogen, a C₁-C₆ alkyl, C₂-C₆ alkenyl, C₃-C₆ aryl or C₂-C₆ alkynyl group (collectively a “C₁-C₆ alkyl, alkenyl, aryl or alkynyl group”) or a benzyl group and X is either S or Se. In one preferred embodiment, each of R¹, R² and R³ is the same. In one aspect of the disclosed and claimed subject matter relates to the use of a compound of formula (R¹R²R³Si)₂S and/or a compound of formula (R¹R²R³Si)₂Se, where R¹, R² and R³ are each independently hydrogen, a C₁-C₆ alkyl, C₂-C₆ alkenyl, C₃-C₆ aryl, benzyl or C₂-C₆ alkynyl group, together with NH₃ for forming a 2D transition metal disulfide and/or diselenide containing film on a substrate.

In one embodiment, each of R¹, R² and R³ is a methyl group and X is sulfur (i.e., “(Me₃Si)₂S” or “TMS₂S”) where it reacts with NH₃ according to the following equation to produce H₂S: (Me₃Si)₂S+NH₃→H₂S+(Me₃Si)₂NH.

In one embodiment, each of R¹, R² and R³ is a methyl group and X is selenium (i.e., “(Me₃Si)₂Se” or “TMS₂Se”) where it reacts with NH₃ according to the following equation to produce H₂Se: (Me₃Si)₂Se+NH₃→H₂Se+(Me₃Si)₂NH.

In another embodiment, the disclosed and claimed subject matter includes the in-situ generation of H₂S and/or H₂Se in CVD deposition processes.

In another embodiment, the disclosed and claimed subject matter includes the in-situ generation of H₂S and/or H₂Se in ALD deposition processes.

### BRIEF DESCRIPTION OF THE DRAWINGS

The accompanying drawings, which are included to provide a further understanding of the disclosed subject matter and are incorporated in and constitute a part of this specification, illustrate embodiments of the disclosed subject matter and together with the description serve to explain the principles of the disclosed subject matter. In the drawings:

FIG. 1 illustrates the Raman spectrum of the resulting MoS₂ film of Example 1. Inset is the average raw background subtracted XRF data for wafers deposited both with and without NH₃ coinjection during the TMS₂S pulse. Note that were XRF data is reported here, it is always raw background subtracted XRF;

FIG. 2 illustrates the Raman spectrum of the resulting MoS₂ film of Example 1. Inset the average XRF data from this run, showing that an optimized MoS₂ film has a much closer to stoichiometric XRF S/Mo ratio. Note that the raw XRF S/Mo ratio for a stoichiometric MoS₂ film has been calibrated as being ~2.1;

FIG. 3 illustrates the XPS composition of the film of Example 1 shown in FIG. 2, showing S/Mo ratio equals 1.9 for this sample while there is neglible Mo—O bonding as witnessed by the lack of a peak at ~235.5 eV binding energy. Si and O are from the SiO₂ substrate, being measured by x-rays that travel through the atomically thin 2D material to the SiO₂ substrate below the MoS₂ film and back to the detector. Carbon content in the film is low and is all or mostly adventitious (one cannot sputter off the surface of an atomically thin 2D film without removing the entire film in the process).

FIG. 4 illustrates the XRF data for both the MoSe₂ film in of Example 3 deposited with NH₃ coinjection during the TMS₂Se ALD pulse and the same ALD deposition but without the NH₃ coinjection;

FIG. 5 illustrates the Raman spectrum of the resulting MoSe₂ film of Example 3; and

FIG. 6 illustrates the XPS of the resulting MoSe₂ film of Example 3.

### DETAILED DESCRIPTION

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the disclosed and claimed subject matter (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the disclosed and claimed subject matter and does not pose a limitation on the scope of the disclosed and claimed subject matter unless otherwise claimed. No language in the specification should be construed as indicating any non-claimed element as essential to the practice of the disclosed and claimed subject matter. The use of the term “comprising” or “including” in the specification and the claims includes the narrower language of “consisting essentially of” and “consisting of.”

Embodiments of the disclosed and claimed subject matter are described herein, including the best mode known to the inventors for carrying out the disclosed and claimed subject matter. Variations of those embodiments may become apparent to those of ordinary skill in the art upon reading the foregoing description. The inventors expect skilled artisans to employ such variations as appropriate, and the inventors intend for the disclosed and claimed subject matter to be practiced otherwise than as specifically described herein. Accordingly, the disclosed and claimed subject matter includes all modifications and equivalents of the subject matter recited in the claims appended hereto as permitted by applicable law. Moreover, any combination of the above-described elements in all possible variations thereof is encompassed by the disclosed and claimed subject matter unless otherwise indicated herein or otherwise clearly contradicted by context.

It will be understood that the term “silicon” as deposited as a material on a microelectronic device will include polysilicon.

For ease of reference, “microelectronic device” or “semiconductor device” corresponds to semiconductor wafers having integrated circuits, memory, and other electronic structures fabricated thereon, and flat panel displays, phase change memory devices, solar panels and other products including solar substrates, photovoltaics, and microelectromechanical systems (MEMS), manufactured for use in microelectronic, integrated circuit, or computer chip applications. Solar substrates include, but are not limited to, silicon, amorphous silicon, polycrystalline silicon, monocrystalline silicon, CdTe, copper indium selenide, copper indium sulfide, and gallium arsenide on gallium. The solar substrates may be doped or undoped. It is to be understood that the term “microelectronic device” or “semiconductor device” is not meant to be limiting in any way and includes any substrate that will eventually become a microelectronic device or microelectronic assembly.

As defined herein, the term “barrier material” corresponds to any material used in the art to seal the metal lines, e.g., copper interconnects, to minimize the diffusion of said metal, e.g., copper, into the dielectric material. Preferred barrier layer materials include tantalum, titanium, ruthenium, hafnium, and other refractory metals and their nitrides and silicides.

As used herein, the terms “about” or “approximately” and the symbol “~” are intended to correspond to within ±5% of the stated value.

“Alkylene” means a linear saturated divalent hydrocarbon radical of one to six carbon atoms or a branched saturated divalent hydrocarbon radical of three to six carbon atoms unless otherwise stated (e.g., methylene, ethylene, propylene, 1-methylpropylene, 2-methylpropylene, butylene, pentylene, and the like).

As used herein, “Cₓ-_{y}” or “Cₓ-C_{y}” (where x and y are each integers) designates the number of carbon atoms in a chain. For example, C₁₋₆ or C₁-C₆ alkyl refers to an alkyl chain having a chain of between 1 and 6 carbons (e.g., methyl, ethyl, propyl, butyl, pentyl and hexyl). Unless specifically stated otherwise, the chain can be linear or branched (i.e., a branched C₃-C₆ alkyl group).

Unless otherwise indicated, “alkyl” refers to hydrocarbon groups which can be linear, branched (e.g., methyl, ethyl, propyl, isopropyl, tert-butyl and the like), cyclic (e.g., cyclohexyl, cyclopropyl, cyclopentyl and the like) or multicyclic (e.g., norbornyl, adamantyl and the like). Suitable acyclic groups can be methyl, ethyl, n- or iso-propyl, n-, iso, or tert-butyl, linear or branched pentyl, hexyl. Unless otherwise stated, alkyl refers to 1-6 carbon atom moieties. The cyclic alkyl groups may be mono cyclic. Suitable example of mono-cyclic alkyl groups include substituted cyclopentyl, cyclohexyl and cycloheptyl groups.

“Heteroalkylene” means an -(alkylene)- radical as defined above where one, two or three carbons in the alkylene chain is replaced by —O—, N(H, alkyl, or substituted alkyl), S, SO, SO₂ or CO. In some preferred embodiments, the carbons are replaced by O or N.

In all such compositions, wherein specific components of the composition are discussed in reference to weight percentage (or “weight %”) ranges including a zero lower limit, it will be understood that such components may be present or absent in various specific embodiments of the composition, and that in instances where such components are present, they may be present at concentrations as low as 0.001 weight percent, based on the total weight of the composition in which such components are employed. Note all percentages of the components are weight percentages and are based on the total weight of the composition, that is, 100%. Any reference to “one or more” or “at least one” includes “two or more” and “three or more” and so on.

Where applicable, all weight percentages unless otherwise indicated are “neat” meaning that they do not include the aqueous solution in which they are present when added to the composition. For example, “neat” refers to the weight % amount of an undiluted acid or other material (i.e., the inclusion 100 g of 85% phosphoric acid constitutes 85 g of the acid and 15 grams of diluent).

Moreover, when referring to the compositions described herein in terms of weight %, it is understood that in no event shall the weight % of all components, including non-essential components, such as impurities, add to more than 100 weight %. In compositions “consisting essentially of” recited components, such components may add up to 100 weight % of the composition or may add up to less than 100 weight %. Where the components add up to less than 100 weight %, such composition may include some small amounts of a non-essential contaminants or impurities. For example, in one such embodiment, the formulation can contain 2% by weight or less of impurities. In another embodiment, the formulation can contain 1% by weight or less than of impurities. In a further embodiment, the formulation can contain 0.05% by weight or less than of impurities. In other such embodiments, the constituents can form at least 90 wt %, more preferably at least 95 wt %, more preferably at least 99 wt %, more preferably at least 99.5 wt %, most preferably at least 99.9 wt %, and can include other ingredients that do not material affect the performance of the wet etchant. Otherwise, if no significant non-essential impurity component is present, it is understood that the composition of all essential constituent components will essentially add up to 100 weight %.

The headings employed herein are not intended to be limiting; rather, they are included for organizational purposes only.

### Exemplary Embodiments

As noted above, the disclosed and claimed subject matter relates to a method for the in-situ production of H₂S and/or H₂Se during the growth of 2D disulfide and/or diselenide containing films by ALD and/or CVD deposition processes. In other words, the disclosed and claimed subject matter relates to a method for forming a 2D transition metal disulfide and/or diselenide containing film on a substrate comprising generating one or more of H₂S and H₂Se in situ in a deposition chamber. As used herein, the term “chemical vapor deposition process” generally refers to any process wherein a substrate is exposed to one or more volatile precursors, which react and/or decompose on the substrate surface to produce the desired deposition and includes ALD and/or CVD deposition processes.

In particular, the disclosed and claimed subject matter relates to a method for the in-situ production of H₂S and/or H₂Se during the growth of 2D transition meta disulfide and/or diselenide containing films by coinjection of (R¹R²R³Si)₂X and NH₃ into a deposition chamber to produce H₂X where R¹, R² and R³ are each independently hydrogen, a C₁-C₆ alkyl, alkenyl, aryl or alkynyl group. In one embodiment, each of R¹, R² and R³ is independently hydrogen, a linear C₁-C₆ alkyl group, a branched C₃-C₆ alkyl group, a C₃-C₆ unsubstituted cyclic alkyl group, a C₃-C₆ aromatic group, a benzyl group, a C₂-C₆ alkenyl group and a C₂-C₆ alkynyl group. In one embodiment, each of R¹, R² and R³ is the same. In one embodiment, at least one of R¹, R² and R³ is different from the others of R¹, R² and R³.

In one embodiment, X is sulfur and each of R¹, R² and R³ is independently hydrogen, a linear C₁-C₆ alkyl group, a branched C₃-C₆ alkyl group, a C₃-C₆ unsubstituted cyclic alkyl group, a C₃-C₆ aromatic group, a benzyl group, a C₂-C₆ alkenyl group and a C₂-C₆ alkynyl group. In one aspect of this embodiment, each of R¹, R² and R³ is the same. In one aspect of this embodiment, at least one of R¹, R² and R³ is different from the others of R¹, R² and R³. In a further aspect of this embodiment, X is sulfur and each of R¹, R² and R³ is a methyl group. In a further aspect of this embodiment, X is sulfur and each of R¹, R² and R³ is a methyl group and is reacted with NH₃ according to the following equation to produce H₂S: (Me₃Si)₂S+NH₃→H₂S+(Me₃Si)₂NH. In yet a further aspect of this embodiment, X is sulfur and R¹ is hydrogen, each of R² and R³ is a methyl group and is reacted with NH₃ according to the following equation to produce H₂S: (Me₂HSi)₂S+NH₃→H₂S+(Me₂HSi)₂NH.

In one embodiment, X is selenium and each of R¹, R² and R³ is independently hydrogen, a linear C₁-C₆ alkyl group, a branched C₃-C₆ alkyl group, a C₃-C₆ unsubstituted cyclic alkyl group, a C₃-C₆ aromatic group, a benzyl group, a C₂-C₆ alkenyl group and a C₂-C₆ alkynyl group. In one aspect of this embodiment, each of R¹, R² and R³ is the same. In one aspect of this embodiment, at least one of R¹, R² and R³ is different from the others of R¹, R² and R³. In a further aspect of this embodiment, X is selenium and each of R¹, R² and R³ is a methyl group. In a further aspect of this embodiment, X is selenium and each of R¹, R² and R³ is a methyl group and is reacted with NH₃ according to the following equation to produce H₂Se: (Me₃Si)₂Se+NH₃→H₂Se+(Me₃Si)₂NH. In yet a further aspect of this embodiment, X is sulfur and R¹ is hydrogen, each of R² and R³ is a methyl group and is reacted with NH₃ according to the following equation to produce H₂Se: (Me₂HSi)₂Se+NH₃→H₂Se+(Me₂HSi)₂NH.

In one embodiment, both H₂S and H₂Se are each generated during the growth of a multi-component 2D film that includes disulfide and diselenide. In this embodiment, (R¹R²R³Si)₂S, (R¹R²R³Si)₂Se and NH₃ are co-injected into a deposition chamber to produce H₂S and H₂Se where R¹, R² and R³ in each formula are each independently hydrogen, a C₁-C₆ alkyl, alkenyl, aryl or alkynyl group or a benzyl group. In one embodiment, each of R¹, R² and R³ is independently a linear C₁-C₆ alkyl group, a branched C₃-C₆ alkyl group, a C₃-C₆ unsubstituted cyclic alkyl group, a C₃-C₆ aromatic group, a benzyl group, a C₂-C₆ alkenyl group and a C₂-C₆ alkynyl group. In one aspect of this embodiment, in the compound (R¹R²R³Si)₂S each of R¹, R² and R³ is a methyl group. In one aspect of this embodiment, in the compound (R¹R²R³Si)₂Se each of R¹, R² and R³ is a methyl group.

As used herein, the term “atomic layer deposition process” or ALD refers to a self-limiting deposition (e.g., the amount of film material deposited in each reaction cycle is surface limited up to a constant “saturated” deposition rate), sequential surface chemistry that deposits films of materials onto substrates of varying compositions. Although the precursors, reagents and sources used herein may be sometimes described as “gaseous,” it is understood that the precursors can be either liquid or solid which are transported with or without an inert gas into the reactor via direct vaporization, bubbling or sublimation. In some case, the vaporized precursors can pass through a plasma generator. The term “reactor” as used herein, includes without limitation, reaction chamber, reaction vessel or deposition chamber.

Chemical vapor deposition processes in which in-situ generated H₂S and/or H₂Se can be utilized include, but are not limited to, those used for the manufacture of semiconductor type microelectronic devices such as ALD and plasma enhanced ALD (PEALD). Thus, in one embodiment, for example, the metal-containing film is deposited using an ALD process. In another embodiment, for example, the metal-containing film is deposited using a plasma enhanced ALD (PEALD) process.

Suitable substrates on which in-situ generated H₂S and/or H₂Se can be used are not particularly limited and vary depending on the final use intended. For example, the substrate may be chosen from oxides such as HfO₂ based materials, TiO₂ based materials, ZrO₂ based materials, rare earth oxide-based materials, ternary oxide-based materials, etc. or from nitride-based films. Other substrates may include solid substrates such as metal substrates (e.g., Au, Pd, Rh, Ru, W, Al, Ni, Ti, Co, Pt and metal silicides (e.g., TiSi₂, CoSi₂, and NiSi₂); metal nitride containing substrates (e.g., TaN, TiN, WN, TaCN, TiCN, TaSiN, and TiSiN); semiconductor materials (e.g., Si, SiGe, GaAs, InP, diamond, GaN, and SiC); insulators (e.g., SiO₂, Si₃N₄, SiON, HfO₂, Ta₂O₅, ZrO₂, TiO₂, Al₂O₃, and barium strontium titanate); combinations thereof. Preferred substrates include HfO₂ based materials, TiO₂ based materials, ZrO₂ based materials, rare earth oxide-based materials, and silicon oxide-based substrates.

The deposition methods and processes may also involve one or more purge gases. The purge gas, which is used to purge away unconsumed reactants and/or reaction byproducts, is an inert gas that does not react with the precursors. Exemplary purge gases include, but are not limited to, argon (Ar), nitrogen (N₂), helium (He), neon, and mixtures thereof. For example, a purge gas such as Ar is supplied into the reactor at a flow rate ranging from about 10 to about 2000 sccm for about 0.1 to 10000 seconds, thereby purging the unreacted material and any byproduct that may remain in the reactor.

The deposition methods and processes may require that energy be applied to the at least one of components used to form the metal-containing film or coating on the substrate. Such energy can be provided by, but not limited to, thermal, plasma, pulsed plasma, helicon plasma, high density plasma, inductively coupled plasma, X-ray, e-beam, photon, remote plasma methods, and combinations thereof. In some processes, a secondary RF frequency source can be used to modify the plasma characteristics at the substrate surface. When utilizing plasma, the plasma-generated process may include a direct plasma-generated process in which plasma is directly generated in the reactor, or alternatively a remote plasma-generated process in which plasma is generated outside of the reactor and supplied into the reactor.

When utilized in such deposition methods and processes suitable precursors and in-situ generated H₂S and/or H₂Se may be delivered to the reaction chamber such as an ALD reactor in a variety of ways. In some instances, a liquid delivery system may be utilized. In other instances, a combined liquid delivery and flash vaporization process unit may be employed, such as, for example, the turbo vaporizer manufactured by MSP Corporation of Shoreview, MN, to enable low volatility materials to be volumetrically delivered, which leads to reproducible transport and deposition without thermal decomposition of the precursor. The precursor compositions described herein can be effectively used as source reagents via direct liquid injection (DLI) to provide a vapor stream of these metal precursors into an ALD reactor.

In view of the forgoing, those skilled in the art will recognize that the disclosed and claimed subject matter further includes a method for forming a 2D transition metal disulfide and/or diselenide containing film on a substrate using in-situ generated H₂S and/or H₂Se in chemical vapor deposition processes as follows.

### CVD

In one aspect, the disclosed and claimed subject matter includes a method for forming a 2D transition metal disulfide and/or diselenide containing film via a chemical vapor deposition (CVD) process that includes the steps of:
(1) contacting a substrate in a deposition chamber with a vapor including
   (a) one or more externally supplied metal precursor and
   (b) one or more of (i) H₂S and (ii) H₂Se; and
(2) optionally purging the vapor with an inert gas,
   where (i) the H₂S is generated in-situ by reacting a compound of the formula (R¹R²R³Si)₂S where R¹, R² and R³ in each formula are each independently hydrogen, a C₁-C₆ alkyl, alkenyl, aryl or alkynyl group or a benzyl group, with NH₃ within the deposition chamber and/or (ii) the H₂Se is generated in-situ by reacting a compound of the formula (R¹R²R³Si)₂Se where R¹, R² and R³ in each formula are each independently hydrogen, a C₁-C₆ alkyl, alkenyl, aryl or alkynyl group or a benzyl group, with NH₃ within the deposition chamber. In a further aspect of this embodiment, (i) the H₂S is generated in-situ by reacting a compound of the formula (R¹R²R³Si)₂S where a linear C₁-C₆ alkyl group, a branched C₃-C₆ alkyl group, a C₃-C₆ unsubstituted cyclic alkyl group, a C₃-C₆ aromatic group, a C₂-C₆ alkenyl group and a C₂-C₆ alkynyl group or a benzyl group with NH₃ within the deposition chamber and/or (ii) the H₂Se is generated in-situ by reacting a compound of the formula (R¹R²R³Si)₂Se where R¹, R² and R³ in each formula are each independently a linear C₁-C₆ alkyl group, a branched C₃-C₆ alkyl group, a C₃-C₆ unsubstituted cyclic alkyl group, a C₃-C₆ aromatic group, a C₂-C₆ alkenyl group and a C₂-C₆ alkynyl group or a benzyl group with NH₃ within the deposition chamber. In a further aspect of this embodiment, (i) the H₂S is generated in-situ by reacting (Me₃Si)₂S+NH₃ within the deposition chamber and (ii) the H₂Se is generated in-situ by reacting (Me₃Si)₂Se+NH₃ within the deposition chamber. In a further aspect of this embodiment, the method consists essentially of steps (i) and (ii). In a further aspect of this embodiment, the method consists of steps (i) and (ii).

### ALD

In one embodiment, the disclosed and claimed subject matter includes a method for forming a 2D transition metal disulfide and/or diselenide containing films via a thermal atomic layer deposition (ALD) process or thermal ALD-like process that includes the steps of:
(1) contacting a substrate in a deposition chamber with a first vapor including one of
   (a) one or more externally supplied metal precursor or
   (b) one or more of (i) H₂S and (ii) H₂Se;
(2) purging the first vapor with an inert gas;
(3) contacting a second vapor including the other of
   (a) the one or more externally supplied metal precursor or
   (b) the one or more of (i) H₂S and (ii) H₂Se;
(4) optionally purging the second vapor with inert gas; and
(5) sequentially repeating steps (1) through (4) until a desired thickness of the metal-containing film is obtained,
   where (i) the H₂S is generated in-situ by reacting a compound of the formula (R¹R²R³Si)₂S where R¹, R² and R³ are each independently hydrogen, a C₁-C₆ alkyl, alkenyl, aryl or alkynyl group or a benzyl group with NH₃ within the deposition chamber and/or (ii) the H₂Se is generated in-situ by reacting a compound of the formula (R¹R²R³Si)₂Se where R¹, R² and R³ are each independently hydrogen, a C₁-C₆ alkyl, alkenyl, aryl or alkynyl group with NH₃ or a benzyl group, within the deposition chamber. In a further aspect of this embodiment, (i) the H₂S is generated in-situ by reacting a compound of the formula (R¹R²R³Si)₂S where R¹, R² and R³ are each independently a linear C₁-C₆ alkyl group, a branched C₃-C₆ alkyl group, a C₃-C₆ unsubstituted cyclic alkyl group, a C₃-C₆ aromatic group, a C₂-C₆ alkenyl group or a C₂-C₆ alkynyl group or a benzyl group with NH₃within the deposition chamber and/or (ii) the H₂Se is generated in-situ by reacting a compound of the formula (R¹R²R³Si)₂Se where R¹, R² and R³ are each independently a linear C₁-C₆ alkyl group, a branched C₃-C₆ alkyl group, a C₃-C₆ unsubstituted cyclic alkyl group, a C₃-C₆ aromatic group, a benzyl group a C₂-C₆ alkenyl group or a C₂-C₆ alkynyl group with NH₃ within the deposition chamber. In a further aspect of this embodiment, (i) the H₂S is generated in-situ by reacting (MeSi)₂S+NH₃ within the deposition chamber and (ii) the H₂Se is generated in-situ by reacting (Me₃Si)₂Se+NH₃ within the deposition chamber. In a further aspect of this embodiment, the method consists essentially of steps (1), (2), (3), (4), and (5). In a further aspect of this embodiment, the method consists of steps (1), (2), (4), and (5).

In a further aspect of this embodiment, the method is conducted at a temperature of about 100° C. to about 650° C. In a further aspect of this embodiment, the method is conducted at a pressure of about 0.1 Torr to about 100 Torr. In a further aspect of this embodiment, the method is conducted at a temperature of about 100° C. to about 650° C. and at a pressure of about 0.1 Torr to about 100 Torr. In a further aspect, the deposition temperatures and pressures are tuned to the one or more externally supplied metal precursor chosen. In a further aspect of this embodiment, the compound of the formula (R¹R²R³Si)₂S where R¹, R² and R³ are each independently hydrogen, a C₁-C₆ alkyl, alkenyl, aryl or alkynyl group or a benzyl group, +NH₃ and/or the compound of the formula (R¹R²R³Si)₂Se where R¹, R² and R³ are each independently a C₁-C₆ alkyl, alkenyl, aryl or alkynyl group or a benzyl group+NH₃ are co-injected into the deposition chamber. In a further aspect of this embodiment, the compound of the formula (R¹R²R³Si)₂S where R¹, R² and R³ are each independently a linear C₁-C₆ alkyl group, a branched C₃-C₆ alkyl group, a C₃-C₆ unsubstituted cyclic alkyl group, a C₃-C₆ aromatic group, a benzyl group, a C₂-C₆ alkenyl group or a C₂-C₆ alkynyl group+NH₃ and/or the compound of the formula (R¹R²R³Si)₂Se where R¹, R² and R³ are each independently a linear C₁-C₆ alkyl group, a branched C₃-C₆ alkyl group, a C₃-C₆ unsubstituted cyclic alkyl group, a C₃-C₆ aromatic group, a benzyl group, a C₂-C₆ alkenyl group or a C₂-C₆ alkynyl group+NH₃ are sequentially injected into the deposition chamber. In a further aspect of this embodiment, TMS₂S+NH₃ and/or TMS₂Se+NH₃ are co-injected into the deposition chamber. In a further aspect of this embodiment, TMS₂S+NH₃ and/or TMS₂Se+NH₃ are sequentially injected into the deposition chamber.

In a further aspect of this embodiment, in step (1) the first vapor includes (a) the one or more externally supplied metal precursor. In a further aspect of this embodiment, in step (1) the first vapor includes (b) one or more of (i) H₂S and (ii) H₂Se. In a further aspect of this embodiment, in step (1) the first vapor includes (i) H₂S. In a further aspect of this embodiment, in step (1) the first vapor includes (ii) H₂Se. In a further aspect of this embodiment, in step (3) the second vapor includes (a) the one or more externally supplied metal precursor. In a further aspect of this embodiment, in step (3) the second vapor includes (b) one or more of (i) H₂S and (ii) H₂Se. In a further aspect of this embodiment, in step (3) the second vapor includes (i) H₂S. In a further aspect of this embodiment, in step (3) the second vapor includes (ii) H₂Se.

### Carrier Gas

In one embodiment of the above-described processes, the one or more externally supplied metal precursor is introduced (i.e., supplied to) into the reaction vessel using a stream of a carrier gas that is one or more of argon, nitrogen, helium, neon and/or krypton. When delivering the one or more externally supplied precursor, the reaction chamber process pressure is between 1 and 50 torr, can preferably between 5 and 20 torr.

### Inert Gas

In one embodiment of the above-described processes, the inert gas is one or more of argon, nitrogen, helium, neon, krypton and combinations thereof.

### Energy Source

In one embodiment of the above-described processes, the method further includes applying energy to one or more externally supplied metal precursor, one or more of (i) H₂S and (ii) H₂Se, the carrier gas (if utilized), the substrate, and combinations thereof, where the energy is one or more of thermal, plasma, pulsed plasma, helicon plasma, high density plasma, inductively coupled plasma, X-ray, e-beam, photon, remote plasma methods and combinations thereof.

### Flow Rate

In one embodiment of the above-described processes, the NH₃ is flowed at from about 50 sccm to about 2000 sccm during the reaction with the compound of the formula (RR²R³Si)₂S (i.e., during the (R¹R²R³Si)₂S pulse) where R¹, R² and R³ are each independently hydrogen, a C₁-C₆ alkyl, alkenyl, aryl or alkynyl group or a benzyl group. In one embodiment, the NH₃ is flowed at from about 100 sccm to about 1500 sccm during the reaction with the compound of the formula (R¹R²R³Si)₂S where R¹, R² and R³ are each independently hydrogen, a C₁-C₆ alkyl, alkenyl, aryl or alkynyl group or a benzyl group. In one embodiment, the NH₃ is flowed at from about 250 sccm to about 1250 sccm during the reaction with the compound of the formula (R¹R²R³Si)₂S where R¹, R² and R³ are each independently hydrogen, a C₁-C₆ alkyl, alkenyl, aryl or alkynyl group or a benzyl group. In one embodiment, the NH₃ is flowed at from about 500 sccm to about 1000 sccm during the reaction with the compound of the formula (R¹R²R³Si)₂S where R¹, R² and R³ are each independently hydrogen, a C₁-C₆ alkyl, alkenyl, aryl or alkynyl group or a benzyl group. In a further aspect of each of the forgoing embodiments, the compound of formula reaction with the compound of the formula (R¹R²R³Si)₂S where R¹, R² and R³ are each independently a C₁-C₆ alkyl, alkenyl, aryl or alkynyl group or a benzyl group includes, consists essentially of or consists of (Me₃Si)₂S.

In one embodiment of the above-described processes, the NH₃ is flowed at about 50 sccm during the reaction with the compound of the formula (R¹R²R³Si)₂S where R¹, R² and R³ are each independently hydrogen, a C₁-C₆ alkyl, alkenyl, aryl or alkynyl group or a benzyl group. In one embodiment, the NH₃ is flowed at about 100 sccm during the reaction with the compound of the formula (R¹R²R³Si)₂S where R¹, R² and R³ are each independently hydrogen, a C₁-C₆ alkyl, alkenyl, aryl or alkynyl group. In one embodiment, the NH₃ is flowed at about 150 sccm during the reaction with the compound of the formula (R¹R²R³Si)₂S where R¹, R² and R³ are each independently hydrogen, a C₁-C₆ alkyl, alkenyl, aryl or alkynyl group or a benzyl group. In one embodiment, the NH₃ is flowed at about 200 sccm during the reaction with the compound of the formula (R¹R²R³Si)₂S where R¹, R² and R³ are each independently hydrogen, a C₁-C₆ alkyl, alkenyl, aryl or alkynyl group or a benzyl group. In one embodiment, the NH₃ is flowed at about 250 sccm during the reaction with the compound of the formula (R¹R²R³Si)₂S where R¹, R² and R³ are each independently hydrogen, a C₁-C₆ alkyl, alkenyl, aryl or alkynyl group or a benzyl group. In one embodiment, the NH₃ is flowed at about 300 sccm during the reaction with the compound of the formula (R¹R²R³Si)₂S where R¹, R² and R³ are each independently hydrogen, a C₁-C₆ alkyl, alkenyl, aryl or alkynyl group or a benzyl group. In one embodiment, the NH₃ is flowed at about 350 sccm during the reaction with the compound of the formula (R¹R²R³Si)₂S where R¹, R² and R³ are each independently hydrogen, a C₁-C₆ alkyl, alkenyl, aryl or alkynyl group or a benzyl group. In one embodiment, the NH₃ is flowed at about 400 sccm during the reaction with the compound of the formula (R¹R²R³Si)₂S where R¹, R² and R³ are each independently hydrogen, a C₁-C₆ alkyl, alkenyl, aryl or alkynyl group or a benzyl group. In one embodiment, the NH₃ is flowed at about 450 sccm during the reaction with the compound of the formula (R¹R²R³Si)₂S where R¹, R² and R³ are each independently hydrogen, a C₁-C₆ alkyl, alkenyl, aryl or alkynyl group or a benzyl group. In one embodiment, the NH₃ is flowed at about 500 sccm during the reaction with the compound of the formula (R¹R²R³Si)₂S where R¹, R² and R³ are each independently hydrogen, a C₁-C₆ alkyl, alkenyl, aryl or alkynyl group or a benzyl group. In one embodiment, the NH₃ is flowed at about 750 sccm during the reaction with the compound of the formula (R¹R²R³Si)₂S where R¹, R² and R³ are each independently hydrogen, a C₁-C₆ alkyl, alkenyl, aryl or alkynyl group or a benzyl group. In one embodiment, the NH₃ is flowed at about 1000 sccm during the reaction with the compound of the formula (R¹R²R³Si)₂S where R¹, R² and R³ are each independently hydrogen, a C₁-C₆ alkyl, alkenyl, aryl or alkynyl group or a benzyl group. In one embodiment, the NH₃ is flowed at about 1250 sccm during the reaction with the compound of the formula (R¹R²R³Si)₂S where R¹, R² and R³ are each independently hydrogen, a C₁-C₆ alkyl, alkenyl, aryl or alkynyl group or a benzyl group. In one embodiment, the NH₃ is flowed at about 1500 sccm during the reaction with the compound of the formula (R¹R²R³Si)₂S where R¹, R² and R³ are each independently hydrogen, a C₁-C₆ alkyl, alkenyl, aryl or alkynyl group or a benzyl group. In one embodiment, the NH₃ is flowed at about 1750 sccm during the reaction with the compound of the formula (R¹R²R³Si)₂S where R¹, R² and R³ are each independently hydrogen, a C₁-C₆ alkyl, alkenyl, aryl or alkynyl group or a benzyl group. In one embodiment, the NH₃ is flowed at about 2000 sccm during the reaction with the compound of the formula (R¹R²R³Si)₂S where R¹, R² and R³ are each independently hydrogen, a C₁-C₆ alkyl, alkenyl, aryl or alkynyl group or a benzyl group. In a further aspect of each of the forgoing embodiments, the compound of formula reaction with the compound of the formula (R¹R²R³Si)₂S where R¹, R² and R³ are each independently hydrogen, a C₁-C₆ alkyl, alkenyl, aryl or alkynyl group or benzyl group includes, consists essentially of or consists of (Me₃Si)₂S.

In one embodiment of the above-described processes, the NH₃ is flowed at from about 50 sccm to about 2000 sccm during the reaction with the compound of the formula (R¹R²R³Si)₂Se (i.e., during the (R¹R²R³Si)₂Se pulse) where R¹, R² and R³ are each independently hydrogen, a C₁-C₆ alkyl, alkenyl, aryl or alkynyl group or benzyl group. In one embodiment, the NH₃ is flowed at from about 100 sccm to about 1500 sccm during the reaction with the compound of the formula (R¹R²R³Si)₂Se where R¹, R² and R³ are each independently hydrogen, a C₁-C₆ alkyl, alkenyl, aryl or alkynyl group or a benzyl group. In one embodiment, the NH₃ is flowed at from about 250 sccm to about 1250 sccm during the reaction with the compound of the formula (R¹R²R³Si)₂Se where R¹, R² and R³ are each independently hydrogen, a C₁-C₆ alkyl, alkenyl, aryl or alkynyl group or a benzyl group. In one embodiment, the NH₃ is flowed at from about 500 sccm to about 1000 sccm during the reaction with the compound of the formula (R¹R²R³Si)₂Se where R¹, R² and R³ are each independently hydrogen, a C₁-C₆ alkyl, alkenyl, aryl or alkynyl group or a benzyl group. In a further aspect of each of the forgoing embodiments, the compound of formula reaction with the compound of the formula (R¹R²R³Si)₂S where R¹, R² and R³ are each independently hydrogen, a C₁-C₆ alkyl, alkenyl, aryl or alkynyl group or benzyl group, includes, consists essentially of or consists of (Me₃Si)₂Se.

In one embodiment of the above-described processes, the NH₃ is flowed at about 50 sccm during the reaction with the compound of the formula (R¹R²R³Si)₂Se where R¹, R² and R³ are each independently hydrogen, a C₁-C₆ alkyl, alkenyl, aryl or alkynyl group or a benzyl group. In one embodiment, the NH₃ is flowed at about 100 sccm during the reaction with the compound of the formula (R¹R²R³Si)₂Se where R¹, R² and R³ are each independently hydrogen, a C₁-C₆ alkyl, alkenyl, aryl or alkynyl group or a benzyl group. In one embodiment, the NH₃ is flowed at about 150 sccm during the reaction with the compound of the formula (R¹R²R³Si)₂Se where R¹, R² and R³ are each independently hydrogen, a C₁-C₆ alkyl, alkenyl, aryl or alkynyl group or a benzyl group. In one embodiment, the NH₃ is flowed at about 200 sccm during the reaction with the compound of the formula (R¹R²R³Si)₂Se where R¹, R² and R³ are each independently hydrogen, a C₁-C₆ alkyl, alkenyl, aryl or alkynyl group or a benzyl group. In one embodiment, the NH₃ is flowed at about 250 sccm during the reaction with the compound of the formula (R¹R²R³Si)₂Se where R¹, R² and R³ are each independently hydrogen, a C₁-C₆ alkyl, alkenyl, aryl or alkynyl group or a benzyl group. In one embodiment, the NH₃is flowed at about 300 sccm during the reaction with the compound of the formula (R¹R²R³Si)₂Se where R¹, R² and R³ are each independently hydrogen, a C₁-C₆ alkyl, alkenyl, aryl or alkynyl group or a benzyl group. In one embodiment, the NH₃ is flowed at about 350 sccm during the TMS₂Se pulse. In one embodiment, the NH₃ is flowed at about 400 sccm during the TMS₂Se pulse. In one embodiment, the NH₃ is flowed at about 450 sccm during the reaction with the compound of the formula (R¹R²R³Si)₂Se where R¹, R² and R³ are each independently hydrogen, a C₁-C₆ alkyl, alkenyl, aryl or alkynyl group or a benzyl group. In one embodiment, the NH₃ is flowed at about 500 sccm during the reaction with the compound of the formula (R¹R²R³Si)₂Se where R¹, R² and R³ are each independently hydrogen, a C₁-C₆ alkyl, alkenyl, aryl or alkynyl group or a benzyl group. In one embodiment, the NH₃ is flowed at about 750 sccm during the reaction with the compound of the formula (R¹R²R³Si)₂Se where R¹, R² and R³ are each independently hydrogen, a C₁-C₆ alkyl, alkenyl, aryl or alkynyl group or a benzyl group. In one embodiment, the NH₃ is flowed at about 1000 sccm during the reaction with the compound of the formula (R¹R²R³Si)₂Se where R¹, R² and R³ are each independently hydrogen, a C₁-C₆ alkyl, alkenyl, aryl or alkynyl group or a benzyl group. In one embodiment, the NH₃ is flowed at about 1250 sccm during the reaction with the compound of the formula (R¹R²R³Si)₂Se where R¹, R² and R³ are each independently hydrogen, a C₁-C₆ alkyl, alkenyl, aryl or alkynyl group or a benzyl group. In one embodiment, the NH₃ is flowed at about 1500 sccm during the reaction with the compound of the formula (R¹R²R³Si)₂Se where R¹, R² and R³ are each independently hydrogen, a C₁-C₆ alkyl, alkenyl, aryl or alkynyl group or a benzyl group. In one embodiment, the NH₃ is flowed at about 1750 sccm during the reaction with the compound of the formula (R¹R²R³Si)₂Se where R¹, R² and R³ are each independently hydrogen, a C₁-C₆ alkyl, alkenyl, aryl or alkynyl group or a benzyl group. In one embodiment, the NH₃ is flowed at about 2000 sccm during the reaction with the compound of the formula (R¹R²R³Si)₂Se where R¹, R² and R³ are each independently hydrogen, a C₁-C₆ alkyl, alkenyl, aryl or alkynyl group or a benzyl group. In a further aspect of each of the forgoing embodiments, the compound of formula reaction with the compound of the formula (R¹R²R³Si)₂Se where R¹, R² and R³ are each independently hydrogen, a C₁-C₆ alkyl, alkenyl, aryl or alkynyl group or benzyl group includes, consists essentially of or consists of (Me₃Si)₂Se.

In one embodiment of the above-described processes, the NH₃ is flowed at substantially the same rate during both the reaction with the compound of the formula (R¹R²R³Si)₂S where R¹, R² and R³ are each independently hydrogen, a C₁-C₆ alkyl, alkenyl, aryl or alkynyl group or a benzyl group and the reaction with the compound of the formula (R¹R²R³Si)₂Se where R¹, R² and R³ are each independently hydrogen, a C₁-C₆ alkyl, alkenyl, aryl or alkynyl group or a benzyl group. In one embodiment of the above-described processes, the NH₃ is flowed at the same rate during both the reaction with the compound of the formula (R¹R²R³Si)₂S where R¹, R² and R³ are each independently hydrogen, a C₁-C₆ alkyl, alkenyl, aryl or alkynyl group or a benzyl group and the reaction with the compound of the formula (R¹R²R³Si)₂Se where R¹, R² and R³ are each independently hydrogen, a C₁-C₆ alkyl, alkenyl, aryl or alkynyl group or a benzyl group. In one embodiment of the above-described processes, the NH₃ is flowed at rate during the reaction with the compound of the formula (R¹R²R³Si)₂S where R¹, R² and R³ are each independently hydrogen, a C₁-C₆ alkyl, alkenyl, aryl or alkynyl group or benzyl group that is different than the rate during the reaction with the compound of the formula (R¹R²R³Si)₂Se where R¹, R² and R³ are each independently hydrogen, a C₁-C₆ alkyl, alkenyl, aryl or alkynyl group or a benzyl group. In a further aspect of each of the forgoing embodiments, the compound of the formula (R¹R²R³Si)₂S where R¹, R² and R³ are each independently hydrogen, a C₁-C₆ alkyl, alkenyl, aryl or alkynyl group or benzyl group includes, consists essentially of or consists of (Me₃Si)₂S and the compound of the formula (R¹R²R³Si)₂Se where R¹, R² and R³ are each independently hydrogen, a C₁-C₆ alkyl, alkenyl, aryl or alkynyl group or benzyl group includes, consists essentially of or consists of (Me₃Si)₂Se.

### Compounds of Formula (R¹R²R³Si)₂S and/or (R¹R²R³Si)₂Se

As described above, various embodiments of the disclosed and claimed processes the formula (R¹R²R³Si)₂S and/or (R¹R²R³Si)₂Se where R¹, R² and R³ are each independently hydrogen, a C₁-C₆ alkyl, alkenyl, aryl or alkynyl group or a benzyl group. In some embodiments, each of R¹, R² and R³ are different. In some embodiments, two of R¹, R² and R³ are the same. In some embodiments, each of R¹, R² and R³ is the same. Suitable R¹, R² and R³ groups include the following.

### Hydrogen

In one embodiment, one or more of R¹, R² and R³ is hydrogen. In one embodiment, two or more of R¹, R² and R³ is hydrogen. In one embodiment, each of R¹, R² and R³ is hydrogen.

### C₁-C₆ Alkyl Groups

C₁-C₆ alkyl groups include linear C₁-C₆ alkyl groups, branched C₃-C₆ alkyl groups and C₃-C₆ unsubstituted cyclic alkyl groups. C₁-C₆ alkyl groups include linear C₁-C₆ alkyl groups, branched C₃-C₆ alkyl groups and C₃-C₆ unsubstituted cyclic alkyl groups. Linear C₁-C₆ alkyl groups include a methyl group, an ethyl group, a propyl group, a butyl group, a pentyl group and a hexyl group. In some embodiments, one or more of R¹, R² and R³ includes a C₁-C₆ alkyl selected from these groups. In one embodiment, one or more of R¹, R² and R³ is a methyl group.

### C₂-C₆ Alkenyl Groups

C₂-C₆ alkenyl groups include linear alkenyls and branched alkenyls. C₂-C₆ linear alkenyls include ethenyl, 1-propenyl, 2-propenyl, 1-butenyl, trans-2-butenyl, cis-2-butenyl, 3-butenyl, 1-pentenyl, trans-2-pentenyl, cis-2-pentenyl, trans-3-pentenyl, cis-3-pentenyl and 4-pentenyl. C₂-C₆ branched alkenyls include isobutene, isopentenyl (2-methylbut-1-enyl, 3-methylbut-1-enyl) and isoamylenyl (2-methylbut-2-enyl). In some embodiments, one or more of R¹, R² and R³ includes a C₂-C₆ alkenyl selected from these groups.

### C₃-C₆ Aryl Groups

C₃-C₆ aryl groups include a C₃-C₆ aromatic groups. In one embodiment, the aromatic group includes a phenyl group.

### Benzyl Group

In one embodiment one or more of R¹, R² and R³ is a benzyl group.

### C₂-C₆ Alkynyl Groups

C₂-C₆ alkynyl groups include ethynyl, propynyl, propargyl, but-1-ynyl, but-2-ynyl and but-3-ynyl.

### Substrate Temperatures

In one embodiment, the substrate temperature is from about 150° C. to about 650° C. In one embodiment, the substrate temperature is from about 200° C. to about 600° C. In one embodiment, the substrate temperature is from about 250° C. to about 550° C. In one embodiment, the substrate temperature is from about 300° C. to about 500° C. In one embodiment, the substrate temperature is from about 325° C. to about 400° C.

In one embodiment, the substrate temperature is about 150° C. In one embodiment, the substrate temperature is about 200° C. In one embodiment, the substrate temperature is about 250° C. In one embodiment, the substrate temperature is about 300° C. In one embodiment, the substrate temperature is about 350° C. In one embodiment, the substrate temperature is about 400° C. In one embodiment, the substrate temperature is about 450° C. In one embodiment, the substrate temperature is about 500° C. In one embodiment, the substrate temperature is about 550° C. In one embodiment, the substrate temperature is about 600° C. In one embodiment, the substrate temperature is about 650° C.

### Metal Precursors

In one embodiment of the above-described processes, the metal precursor includes one or more of MoO₂Cl₂, MoO₂Br₂, MoCl₅, MoCl₆, MoOCl₄, WO₂Cl₂, WCl₄, WCl₅, WCl₆, WOCl₄, TiCl₄, ZrCl₄, HfCl₄, TaCl₄, TaCl₅, NbCl₄, NbCl₅ and/or various other precursors of these elements or other TMD forming elements and/or combinations thereof. In one embodiment of the above-described processes, the metal precursor includes MoO₂Cl₂. In one embodiment of the above-described processes, the metal precursor includes MoO₂Br₂. In one embodiment of the above-described processes, the metal precursor includes MoCl₅. In one embodiment of the above-described processes, the metal precursor includes MoCl₆. In one embodiment of the above-described processes, the metal precursor includes MoOCl₄. In one embodiment of the above-described processes, the metal precursor includes WO₂Cl₂. In one embodiment of the above-described processes, the metal precursor includes WCl₄. In one embodiment of the above-described processes, the metal precursor includes WCl₆. In one embodiment of the above-described processes, the metal precursor includes WOCl₄. In one embodiment of the above-described processes, the metal precursor includes TiCl₄. In one embodiment of the above-described processes, the metal precursor includes ZrCl₄. In one embodiment of the above-described processes, the metal precursor includes HfCl₄. In one embodiment of the above-described processes, the metal precursor includes TaCl₄. In one embodiment of the above-described processes, the metal precursor includes TaCl₅. In one embodiment of the above-described processes, the metal precursor includes NbCl₄. In one embodiment of the above-described processes, the metal precursor includes NbCl₅.

In another embodiment of the above-described processes, the metal precursor includes one or more of MoBURE (bis(t-butylimido)bis(dimethylamino)molybdenum(VI)), TDMAMo (tetrakis(dimethylamino)molybdenum), TDEAMO (tetrakis(diethylamino)molybdenum), TEMAMo (tetrakis(ethylmethylamino)molybdenum), WNBURE (bis(t-butylimido)bis(dimethylamino)tungsten(VI)), TEMAZ (tetrakis(ethylmethylamino)zirconium), TEMAHf (tetrakis(ethylmethylamino)hafnium), TEMAT (tetrakis(ethylmethylamino)titanium), TDMAT (tetrakis(dimethylmethylamino)titanium), TDEAT (tetrakis(diethylmethylamino)titanium), TBTDMT ((t-butylimido)tris(dimethylamino)tantanlum), TBTDET ((t-butylimido)tris(diethylamino)tantanlum), TEMAV (tetrakis(ethylmethylamino)vanadium), various other precursors of these elements or other TMD forming elements and/or combinations thereof. In another embodiment of the above-described processes, the metal precursor includes MoBURE (Bis(t-butylimido)bis(dimethylamino)molybdenum(VI)). In another embodiment of the above-described processes, the metal precursor includes TDMAMo. In another embodiment of the above-described processes, the metal precursor includes TEMAMo. In another embodiment of the above-described processes, the metal precursor gas includes WNBURE (Bis(t-butylimido)bis(dimethylamino)tungsten(VI)). In another embodiment of the above-described processes, the metal precursor includes TEMAZ. In another embodiment of the above-described processes, the metal precursor includes TEMAHf. In another embodiment of the above-described processes, the metal precursor includes TEMAT. In another embodiment of the above-described processes, the metal precursor includes TDMAT. In another embodiment of the above-described processes, the metal precursor includes TDEAT.

### EXAMPLES

Reference will now be made to more specific embodiments of the present disclosure and experimental results that provide support for such embodiments. The examples are given below to more fully illustrate the disclosed and claimed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

### Materials and Methods

All reactions and manipulations described in the examples were conducted under an argon atmosphere using an Intermolecular A30 ALD chamber. All chemicals were received from Versum Materials and Millipore-Sigma (EMD Electronics).

### Specific Examples

### Example 1: In-Situ Production of H₂S to Yield MoS₂ Film

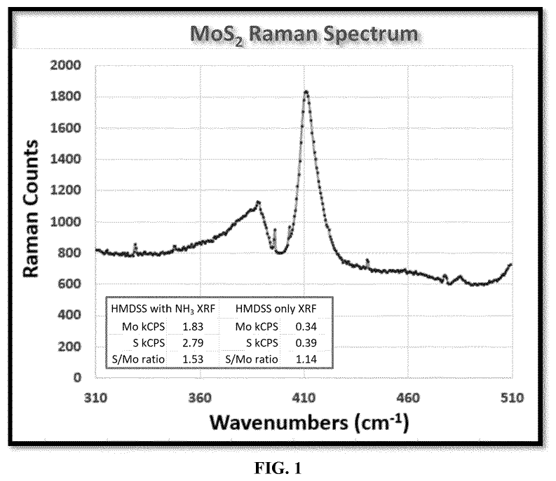

FIG. 1 shows the Raman spectrum of a 2D MoSₓ film grown using MoO₂Cl₂ as the Mo metal precursor and TMS₂S with NH₃ coinjection the in-situ H₂S source grown for 100 cycles ALD cycles. The inset box shows the XRF counts with and without NH₃ coinjection during the TMS₂S pulse, showing that there 545% greater growth of the MoSₓ 2D film with NH₃ coinjection, and there is virtually no MoSₓ growth without NH₃ coinjection during the TMS₂S pulse that is also very nonstoichiometric. Note that, in the NH₃ coinjection case, the MoSₓ is sulfur deficient (x is ~1.5 instead of 2.0), which is due to comparing a film that has the same delivery conditions as the deposition without NH₃ coinjection (that is, an unoptimized ALD process).

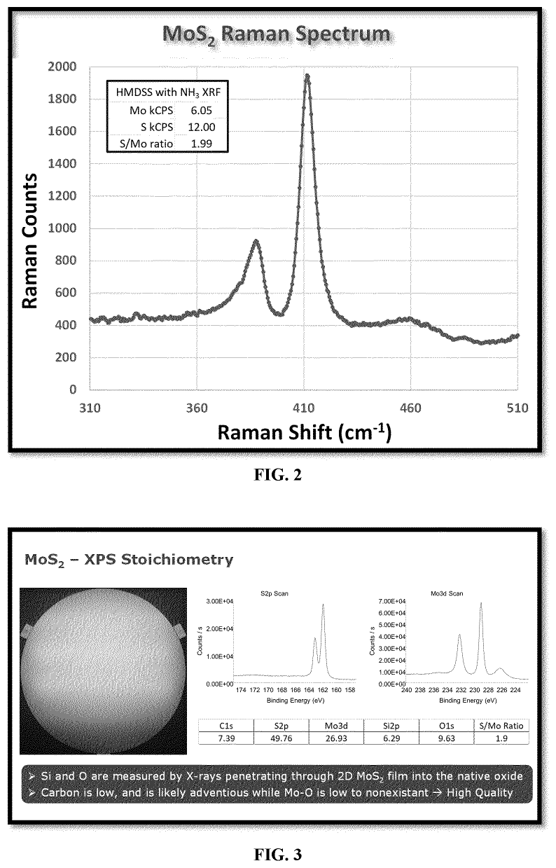

As shown in FIG. 2, an optimized ALD process with NH₃ injection during the TMS₂S pulse with the same Mo precursor yields MoS1.9 thin films, which is very far from the near non-reaction that MoO₂Cl₂ and TMS₂S have without the NH₃ coinjection, proving that H₂S was produced in-situ by NH₃ coinjection with TMS₂S in the same ALD pulse.

As shown in FIG. 3, XPS composition of the optimized ALD process with NH₃ injection during the TMS₂S pulse shown in FIG. 2, showing S/Mo ratio equals 1.9 for this sample while there is neglible Mo—O bonding as witnessed by the lack of a peak at ~235.5 eV binding energy. Si and O are from the SiO₂ substrate, being measured by x-rays that travel through the atomically thin 2D material to the SiO₂ substrate below the MoS₂ film and back to the detector. Carbon content in the film is low and is all or mostly adventitious (one cannot sputter off the surface of an atomically thin 2D film without removing the entire film in the process).

### Example 2: In-Situ Production of H₂Se to Yield MoSe₂ Film

In-situ H₂Se production using NH₃ co-injection during the TMS₂Se pulses during an ALD or CVD process is evidenced by the large change in deposition rate when NH₃ is added to the process compared to without any NH₃.

FIG. 4 illustrates the difference in XRF Mo counts and XRF Se counts from having NH₃ coinjection during the TMS₂Se pulse vs only having a pure TMS₂Se pulse. As shown in FIG. 4, NH₃ injection during the TMS₂Se pulses in an ALD MoSe₂ process with a Mo precursor greatly increases the yield of MoSe₂ thin film. The 370% increase in film thickness with NH₃ coinjection, and the Raman in FIG. 4 show that this is attributable to in-situ H₂Se production. Note that for MoSe₂, the raw XRF Se/Mo count ratio for a stoichiometric film is ~0.6, so the XPS Se/Mo ratio is also listed to the left of the table, which equals 1.9.

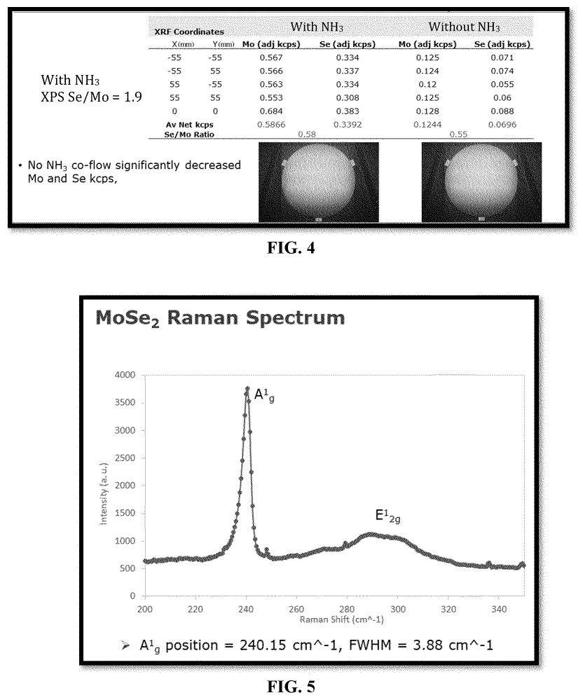

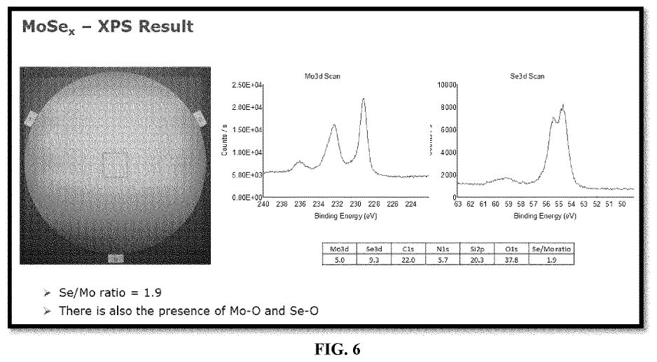

FIG. 5 illustrates the Raman spectrum of the resulting MoSe_{~1.9-2.1} films grown with NH₃ coinjection during the TMS₂Se pulses in Example 2. As shown in FIG. 5, co-injection of NH₃ during the TMS₂Se pulse yields a 2D MoSe_{~1.9-2.1} film with narrow A 1 g full width at half maximum.

FIG. 6 illustrates the XPS of the resulting MoSe₂ films grown in Example 2. As shown in FIG. 6, the XPS Se/Mo ratio for this sample's 2D MoSe₂ film is 1.9.

The foregoing description is intended primarily for purposes of illustration. Although the disclosed and claimed subject matter has been shown and described with respect to an exemplary embodiment thereof, it should be understood by those skilled in the art that the foregoing and various other changes, omissions, and additions in the form and detail thereof may be made therein without departing from the spirit and scope of the disclosed and claimed subject matter.

1. A method for forming a 2D transition metal disulfide and/or diselenide containing film on a substrate comprising generating one or more of H₂S and H₂Se in situ in a deposition chamber, wherein the forming of the 2D transition metal disulfide and/or diselenide containing film comprises one of:
(A) a chemical vapor deposition (CVD) process comprising the steps of:
(1) contacting a substrate in a deposition chamber with a vapor including
(a) one or more externally supplied metal precursor and
(b) one or more of (i) H₂S and (ii) H₂Se; and
(2) optionally purging the vapor with an inert gas, or
(B) a thermal atomic layer deposition (ALD) process or thermal ALD-like process comprising the steps of:
(1) contacting a substrate in a deposition chamber with a first vapor including one of
(a) one or more externally supplied metal precursor or
(b) one or more of (i) H₂S and (ii) H₂Se;
(2) purging the first vapor with an inert gas;
(3) contacting a second vapor including the other of
(a) the one or more externally supplied metal precursor or
(b) the one or more of (i) H₂S and (ii) H₂Se;
(4) optionally purging the second vapor with inert gas; and
(5) sequentially repeating steps (1) through (4) until a desired thickness of the metal-containing film is obtained,
wherein
(i) the H₂S is generated in-situ by reacting a compound of formula (R¹R²R³Si)₂S wherein R¹, R² and R³ are each independently hydrogen, a C₁-C₆ alkyl, C₂-C₆ alkenyl, C₃-C₆ aryl, benzyl or C₂-C₆ alkynyl group +NH₃ within the deposition chamber, and
(ii) the H₂Se is generated in-situ by reacting a compound of formula (R¹R²R³Si)₂Se wherein R¹, R² and R³ are each independently hydrogen, a C₁-C₆ alkyl, C₂-C₆ alkenyl, C₃-C₆ aryl, benzyl or C₂-C₆ alkynyl group+NH₃ within the deposition chamber.

2-9. (canceled)

10. The process of claim 1, wherein one or more of R¹, R² and R³ comprises a C₁-C₆ alkyl group, a branched C₃-C₆ alkyl group or a C₃-C₆ unsubstituted cyclic alkyl group.

11. The process of claim 1, wherein one or more of R¹, R² and R³ comprises a C₁-C₆ alkyl group.

12. (canceled)

13. (canceled)

14. The process of claim 1, wherein one or more of R¹, R² and R³ comprises a C₁-C₆ alkyl group selected from the group of a methyl group, an ethyl group, a propyl group, a butyl group, a pentyl group and a hexyl group.

15. The process of claim 1, wherein one or more of R¹, R² and R³ comprises a methyl group.

16. The process of claim 1, wherein one or more of R¹, R² and R³ comprises a C₂-C₆ alkenyl group selected from a linear alkenyl group and a branched alkenyl group.

17. (canceled)

18. (canceled)

19. The process of claim 1, wherein one or more of R¹, R² and R³ comprises a C₂-C₆ linear alkenyl group selected from the group of ethenyl, 1-propenyl, 2-propenyl, 1-butenyl, trans-2-butenyl, cis-2-butenyl, 3-butenyl, 1-pentenyl, trans-2-pentenyl, cis-2-pentenyl, trans-3-pentenyl, cis-3-pentenyl and 4-pentenyl.

20. The process of claim 1, wherein one or more of R¹, R² and R³ comprises a C₂-C₆ branched alkenyl group selected from isobutenyl, isopentenyl (2-methylbut-1-enyl, 3-methylbut-1-enyl) and isoamylenly (2-methylbut-2-enyl).

21. The process of claim 1, wherein one or more of R¹, R² and R³ comprises a C₃-C₆ aryl group.

22. The process of claim 1, wherein one or more of R¹, R² and R³ comprises a C₃-C₆ aryl group that is an aromatic group.

23. The process of claim 1, wherein one or more of R¹, R² and R³ comprises a phenyl group.

24. The process of claim 1, wherein one or more of R¹, R² and R³ comprises a benzyl group.

25. The process of claim 1, wherein one or more of R¹, R² and R³ comprises a C₂-C₆ alkynyl group.

26. The process of claim 1, wherein one or more of R¹, R² and R³ comprises a C₂-C₆ alkynyl group selected from the group of ethynyl, propynyl, propargyl, but-1-ynyl, but-2-ynyl and but-3-ynyl.

27. The process of claim 1, wherein (i) the H₂S is generated in-situ by reacting TMS₂S+NH₃ within the deposition chamber.

28. The process of claim 1, wherein (ii) the H₂Se is generated in-situ by reacting TMS₂Se+NH₃ within the deposition chamber.

29. The process of claim 1, wherein the NH₃is flowed at from about 50 sccm to about 2000 sccm during the (R¹R²R³Si)₂S pulse.

30-36. (canceled)

37. The process of claim 1, wherein the substrate temperature is from about 150° C. to about 650° C.

38-41. (canceled)

42. The process of claim 1, wherein the metal precursor gas comprises one or more of MoO₂Cl₂, MoCl₅, MoCl₆, MoOCl₄, WO₂Cl₂, WCl₄, WCl₅, WCl₆, WOCl₄, TiCl₄, ZrCl₄, HfCl₄, TaCl₄, TaCl₅, NbCl₄, NbCl₅ and combinations thereof.

43-58. (canceled)

59. The process of claim 1, wherein the metal precursor comprises one or more of MoBURE (Bis(t-butylimido)bis(dimethylamino)molybdenum(VI)), TDMAMo, TDEAMo, TEMAMo, WNBURE (Bis(t-butylimido)bis(dimethylamino)tungsten(VI)), TEMAZ, TEMAHf, TEMAT, TDMAT, TDEAT and combinations thereof.

60-82. (canceled)
